(19) United States
(12) Patent Application Publication
(10) Pub. No.: US 2023/0136407 A1
(43) Pub. Date: May 4, 2023

(54) LIQUID COOLING MODULE AND ELECTRONIC DEVICE

(71) Applicants: Inventec (Pudong) Technology Corp., Shanghai (CN); Inventec Corporation, Taipei (TW)

(72) Inventors: Po-An Chen, Taipei (TW); Jie-Wei Chang, Taipei (TW)

(73) Assignees: Inventec (Pudong) Technology Corp., Shanghai (CN); Inventec Corporation, Taipei (TW)

(21) Appl. No.: 17/527,099

(22) Filed: Nov. 15, 2021

(30) Foreign Application Priority Data
Nov. 4, 2021 (CN) 202111299345.8

(51) Int. Cl. H05K 7/20

(52) U.S. Cl. CPC H05K 7/20263

(57) ABSTRACT

A liquid cooling module includes a heat dissipating base, a replaceable fin structure and a cover. The heat dissipating base includes a substrate and the substrate has a fin accommodating region. The replaceable fin structure includes a plurality of fins. The replaceable fin structure is detachably disposed on the fin accommodating region. The cover is disposed on the substrate and covers the replaceable fin structure.

### BACKGROUND OF THE INVENTION

### 1. Field of the Invention

The invention relates to a liquid cooling module and, more particularly, to a liquid cooling module with a replaceable fin structure and an electronic device equipped with the liquid cooling module.

### 2. Description of the Prior Art

As the speed and performance of an electronic component (e.g. central processing unit) in a server increase, more and more servers use a liquid cooling module to dissipate heat from the electronic component to improve heat dissipating efficiency. Referring to FIG. 1, FIG. 1 is a perspective view illustrating a heat dissipating base 30 of the prior art. As shown in FIG. 1, the fins 32 are formed on the heat dissipating base 30 integrally. In general, a liquid cooling module has the heat dissipating base 30 shown in FIG. 1 and the heat dissipating base 30 is attached on an electronic component. Heat generated by the electronic component is conducted to the fins 32 of the heat dissipating base 30 and then dissipated by a cooling liquid passing through the fins 32. Since the heat dissipating base 30 with the fins 32 is made of a material with high thermal conductivity, the manufacturing and material cost is high. During the development of the server, it is usually necessary to manufacture the heat dissipating base 30 with the fins 32 of different shapes for the electronic component with different power to test the heat dissipating efficiency. Consequently, a large number of heat dissipating bases 30 with the fins 32 of different shapes need to be manufactured, thereby increasing the manufacturing cost and the development cycle.

### Summary of the Invention

The invention provides a liquid cooling module with a replaceable fin structure and an electronic device equipped with the liquid cooling module, so as to solve the aforesaid problems.

According to an embodiment of the invention, a liquid cooling module comprises a heat dissipating base, a replaceable fin structure and a cover. The heat dissipating base comprises a substrate and the substrate has a fin accommodating region. The replaceable fin structure comprises a plurality of fins. The replaceable fin structure is detachably disposed on the fin accommodating region. The cover is disposed on the substrate and covers the replaceable fin structure.

According to another embodiment of the invention, an electronic device comprises a casing, an electronic component and a liquid cooling module. The electronic component is disposed in the casing. The liquid cooling module is disposed in the casing. The liquid cooling module comprises a heat dissipating base, a replaceable fin structure and a cover. The heat dissipating base is disposed on the electronic component. The heat dissipating base comprises a substrate and the substrate has a fin accommodating region. The replaceable fin structure comprises a plurality of fins. The replaceable fin structure is detachably disposed on the fin accommodating region. The cover is disposed on the substrate and covers the replaceable fin structure.

As mentioned in the above, the replaceable fin structure of the invention is detachably disposed on the fin accommodating region of the heat dissipating base. Thus, the invention can rapidly replace the replaceable fin structure with the fins of different shapes for the electronic component with different power to test the heat dissipating efficiency. Accordingly, the heat dissipating base does not need to be remanufactured, thereby effectively reducing the manufacturing cost and the development cycle. Furthermore, since the replaceable fin structure is an independent component with small volume and few processing restrictions, the arrangement and shape of the fins of the replaceable fin structure can be more diversified to satisfy various heat dissipating requirements.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a heat dissipating base of the prior art.

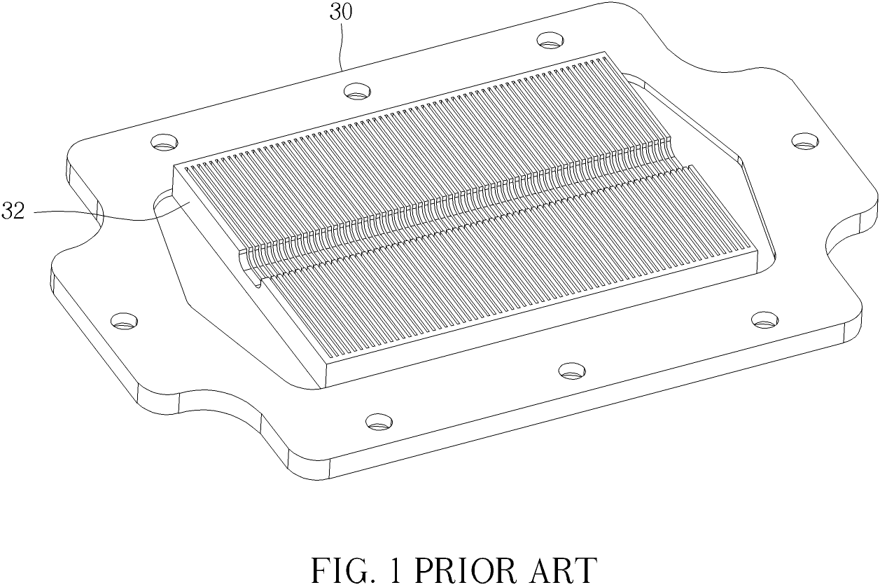

FIG. 2 is a perspective view illustrating a liquid cooling module according to an embodiment of the invention.

FIG. 3 is a sectional view illustrating an electronic device equipped with the liquid cooling module shown in FIG. 2.

FIG. 4 is an exploded view illustrating the liquid cooling module shown in FIG. 2.

FIG. 5 is a perspective view illustrating the liquid cooling module shown in FIG. 2 from another viewing angle.

FIG. 6 is an exploded view illustrating the liquid cooling module shown in FIG. 5.

FIG. 7 is a perspective view illustrating three replaceable fin structures with fins of different shapes.

### DETAILED DESCRIPTION

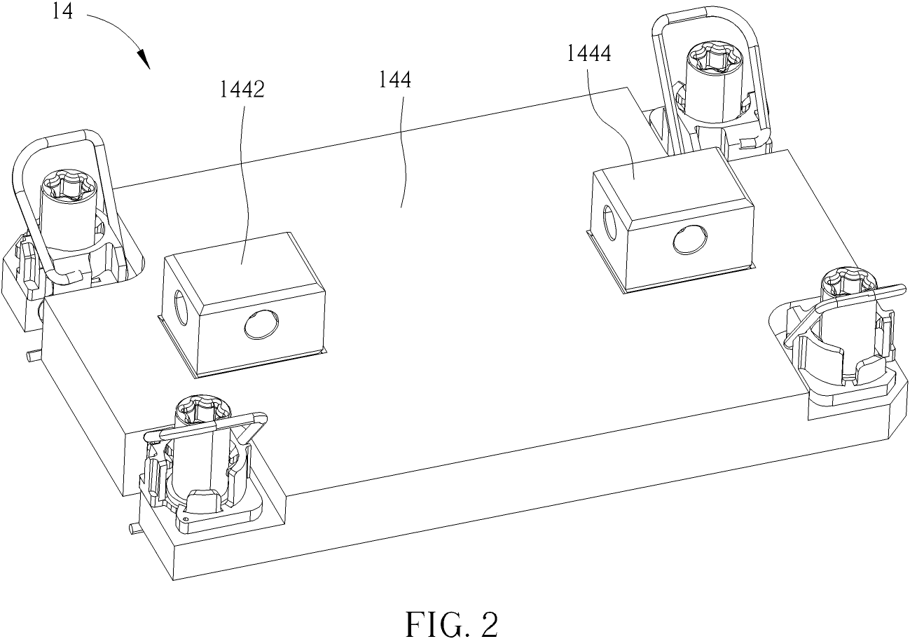

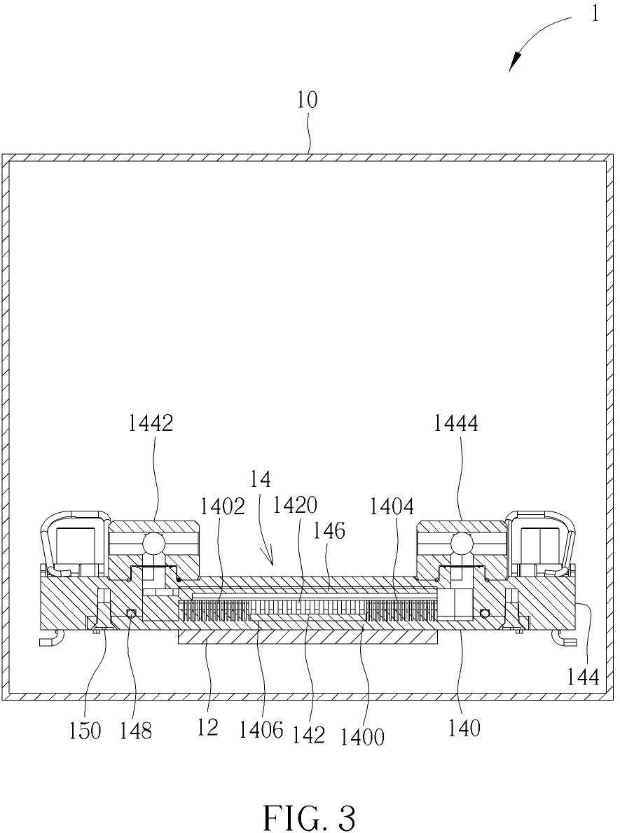

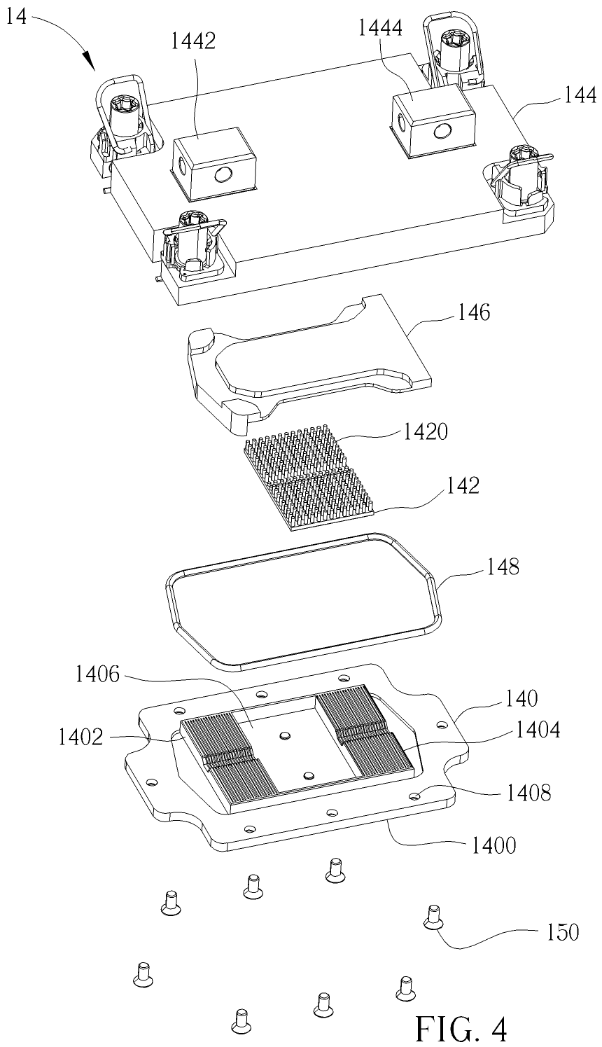

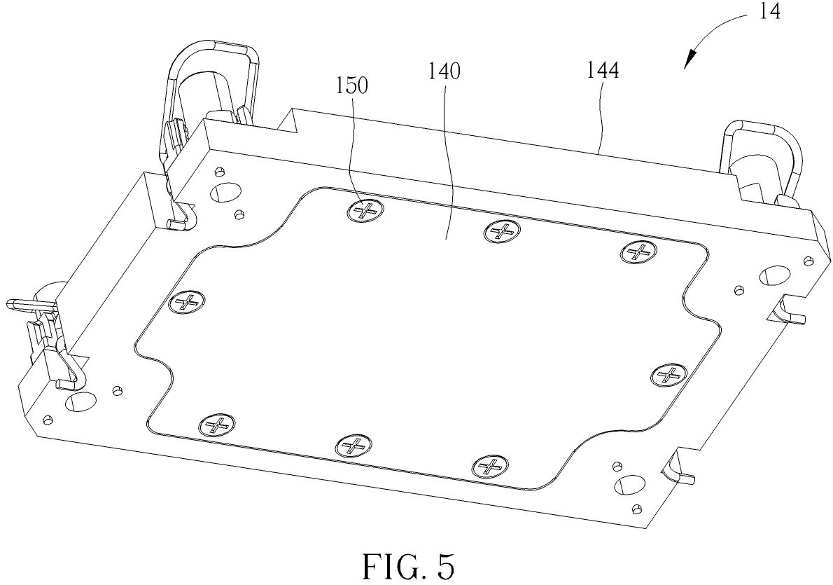

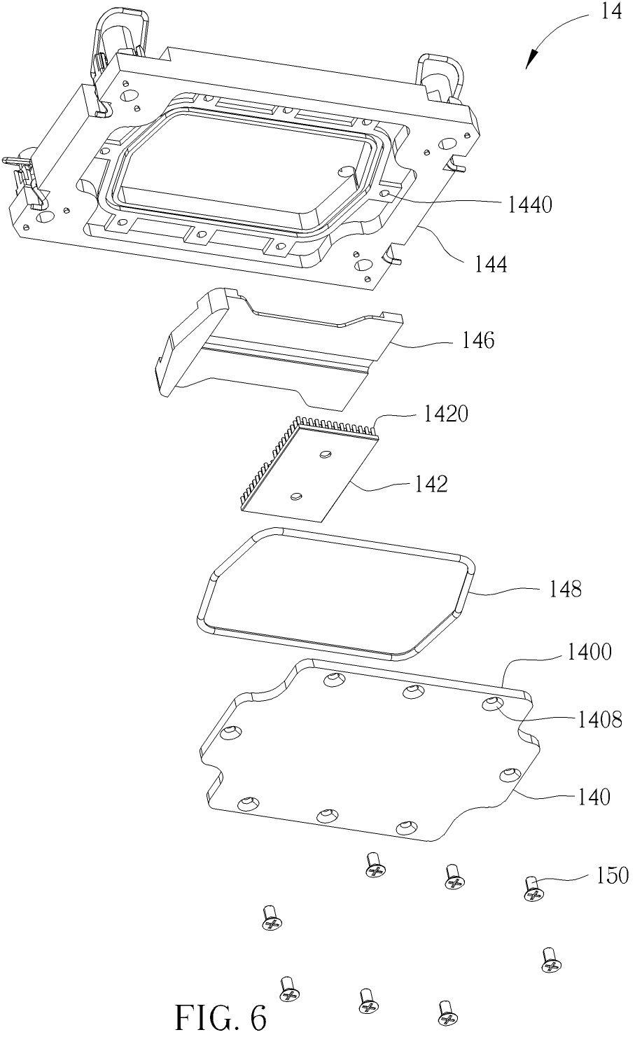

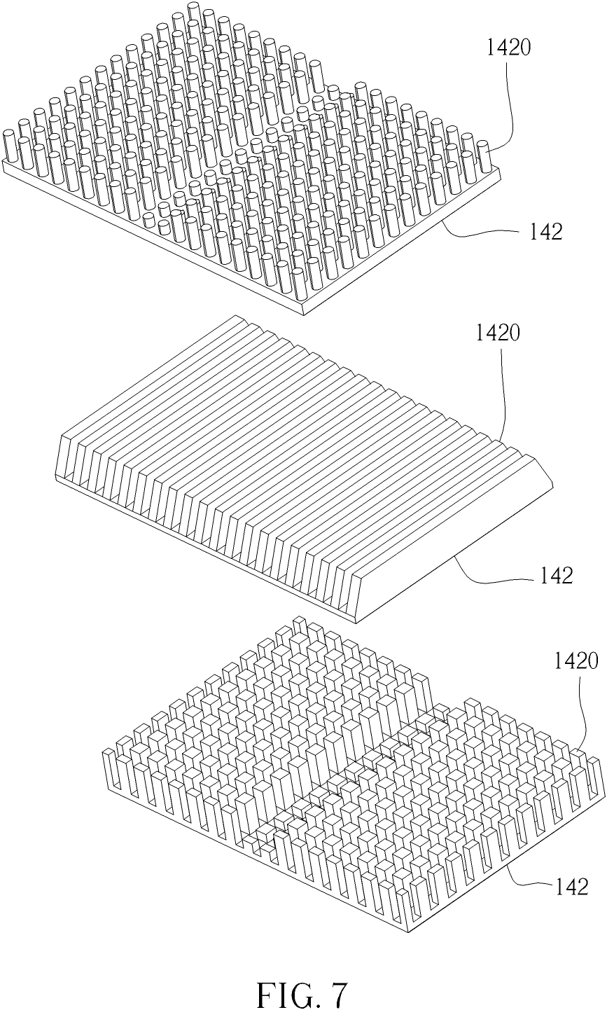

Referring to FIGS. 2 to 7, FIG. 2 is a perspective view illustrating a liquid cooling module 14 according to an embodiment of the invention, FIG. 3 is a sectional view illustrating an electronic device 1 equipped with the liquid cooling module 14 shown in FIG. 2, FIG. 4 is an exploded view illustrating the liquid cooling module 14 shown in FIG. 2, FIG. 5 is a perspective view illustrating the liquid cooling module 14 shown in FIG. 2 from another viewing angle, FIG. 6 is an exploded view illustrating the liquid cooling module 14 shown in FIG. 5, and FIG. 7 is a perspective view illustrating three replaceable fin structures 142 with fins of different shapes.

As shown in FIG. 3, the electronic device 1 comprises a casing 10, an electronic component 12 and a liquid cooling module 14. The electronic device 1 may be a computer, a server or other electronic devices according to practical applications. The electronic component 12 and the liquid cooling module 14 are disposed in the casing 10. The liquid cooling module 14 is disposed on the electronic component 12 to dissipate heat from the electronic component 12. The electronic component 12 may be a central processing unit or other electronic components according to practical applications. In general, the electronic device 1 may be further equipped with some necessary hardware and software components for specific purposes, such as circuit board, memory, power supply, applications, communication module, etc., and it depends on practical applications.

As shown in FIGS. 2 to 6, the liquid cooling module 14 comprises a heat dissipating base 140, a replaceable fin structure 142, a cover 144, a resilient member 146, a sealing ring 148 and a plurality of fixing members 150. The heat dissipating base 140 is disposed on the electronic component 12. The heat dissipating base 140 comprises a substrate 1400, a first fixed fin structure 1402 and a second fixed fin structure 1404. Furthermore, the substrate 1400 has a fin accommodating region 1406. The first fixed fin structure 1402 extends from the substrate 1400 and is adjacent to a side of the fin accommodating region 1406. The second fixed fin structure 1404 extends from the substrate 1400 and is adjacent to another side of the fin accommodating region 1406. Thus, the fin accommodating region 1406 is located between the first fixed fin structure 1402 and the second fixed fin structure 1404. In this embodiment, the first fixed fin structure 1402 and the second fixed fin structure 1404 may be formed on the heat dissipating base 140 integrally. It should be noted that, in another embodiment, the heat dissipating base 140 may not comprise the first fixed fin structure 1402 and/or the second fixed fin structure 1404. That is to say, the first fixed fin structure 1402 and the second fixed fin structure 1404 may be selectively disposed on the heat dissipating base 140 according to practical applications.

The replaceable fin structure 142 is detachably disposed on the fin accommodating region 1406 of the heat dissipating base 140. In this embodiment, the replaceable fin structure 142 comprises a plurality of fins 1420, wherein each of the fins 1420 may be strip, square or circular. As shown in FIG. 7, this embodiment may provide three replaceable fin structures 142 with the fins 1420 of different shapes. It should be noted that the number of the replaceable fin structures 142 and the arrangement and shape of the fins 1420 may be determined according to practical applications, so the invention is not limited to the embodiment shown in the figure.

The resilient member 146 is disposed between the replaceable fin structure 142 and the cover 144. The cover 144 is disposed on the substrate 1400 of the heat dissipating base 140 and covers the replaceable fin structure 142 and the resilient member 146. In this embodiment, the resilient member 146 may be made of rubber or other resilient materials. The sealing ring 148 is disposed between the substrate 1400 of the heat dissipating base 140 and the cover 144. In this embodiment, the sealing ring 148 may be an O-ring. The fixing members 150 are used to fix the substrate 1400 of the heat dissipating base 140 to the cover 144. In this embodiment, the fixing members 150 may be screws.

To assemble the liquid cooling module 14, a user may dispose the replaceable fin structure 142 on the fin accommodating region 1406 of the heat dissipating base 140 first. Then, the user may dispose the resilient member 146 on the replaceable fin structure 142 and dispose the sealing ring 148 on the substrate 1400 of the heat dissipating base 140. Finally, the user may insert the fixing members 150 into the through holes 1408 of the substrate 1400 and fix the fixing members 150 to the fixing holes 1440 of the cover 144. Consequently, the assembly of the liquid cooling module 14 is finished. After the assembly of the liquid cooling module 14 is finished, the cover 144 compresses the resilient member 146 downward, such that the resilient member 146 tightly forces the replaceable fin structure 142 on the substrate 1400 of the heat dissipating base 140. In addition, the invention may further utilize the elastic deformation of the resilient member 146 to absorb the assembly tolerance between the components, such that the replaceable fin structure 142 is completely fixed on the substrate 1400 of the heat dissipating base 140. The sealing ring 148 is used to seal a gap between the substrate 1400 of the heat dissipating base 140 and the cover 144.

Moreover, the cover 144 comprises a liquid inlet 1442 and a liquid outlet 1444. After the assembly of the liquid cooling module 14 is finished, the fin accommodating region 1406 of the heat dissipating base 140 is located between the liquid inlet 1442 and the liquid outlet 1444. In other words, the invention may utilize the space between the liquid inlet 1442 and the liquid outlet 1444 to dispose the replaceable fin structure 142. As shown in FIG. 3, a cooling liquid (not shown) flows into the liquid cooling module 14 from the liquid inlet 1442 of the cover 144, flows through the first fixed fin structure 1402, the replaceable fin structure 142 and the second fixed fin structure 1404, and then flows out of the liquid cooling module 14 from the liquid outlet 1444 of the cover 144.

When a user wants to replace the replaceable fin structure 142, the user only needs to disassemble the fixing members 150, the cover 144 and the resilient member 146 sequentially. Accordingly, the user can rapidly replace the replaceable fin structure 142 with the fins 1420 of different shapes for the electronic component 12 with different power to test the heat dissipating efficiency.

As mentioned in the above, the replaceable fin structure of the invention is detachably disposed on the fin accommodating region of the heat dissipating base. Thus, the invention can rapidly replace the replaceable fin structure with the fins of different shapes for the electronic component with different power to test the heat dissipating efficiency. Accordingly, the heat dissipating base does not need to be remanufactured, thereby effectively reducing the manufacturing cost and the development cycle. Furthermore, since the replaceable fin structure is an independent component with small volume and few processing restrictions, the arrangement and shape of the fins of the replaceable fin structure can be more diversified to satisfy various heat dissipating requirements.

In an embodiment of the invention, the liquid cooling module and the electronic device of the invention may be applied to a server, wherein the server may not only be applied to artificial intelligence (AI) and edge computing, but also be used as a 5G server, a cloud server or an Internet of Vehicles server.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A liquid cooling module comprising:
a heat dissipating base comprising a substrate, the substrate having a fin accommodating region;
a replaceable fin structure comprising a plurality of fins, the replaceable fin structure being detachably disposed on the fin accommodating region; and
a cover disposed on the substrate and covering the replaceable fin structure.

2. The liquid cooling module of claim 1, wherein the heat dissipating base further comprises a first fixed fin structure and a second fixed fin structure, the first fixed fin structure extends from the substrate and is adjacent to the fin accommodating region, the second fixed fin structure extends from the substrate and is adjacent to the fin accommodating region, and the fin accommodating region is located between the first fixed fin structure and the second fixed fin structure.

3. The liquid cooling module of claim 1, further comprising a resilient member disposed between the replaceable fin structure and the cover.

4. The liquid cooling module of claim 1, further comprising a sealing ring disposed between the substrate and the cover.

5. The liquid cooling module of claim 1, wherein the cover comprises a liquid inlet and a liquid outlet, and the fin accommodating region is located between the liquid inlet and the liquid outlet.

6. An electronic device comprising:
a casing;
an electronic component disposed in the casing; and
a liquid cooling module disposed in the casing, the liquid cooling module comprising:
a heat dissipating base disposed on the electronic component, the heat dissipating base comprising a substrate, the substrate having a fin accommodating region;
a replaceable fin structure comprising a plurality of fins, the replaceable fin structure being detachably disposed on the fin accommodating region; and
a cover disposed on the substrate and covering the replaceable fin structure.

7. The electronic device of claim 6, wherein the heat dissipating base further comprises a first fixed fin structure and a second fixed fin structure, the first fixed fin structure extends from the substrate and is adjacent to the fin accommodating region, the second fixed fin structure extends from the substrate and is adjacent to the fin accommodating region, and the fin accommodating region is located between the first fixed fin structure and the second fixed fin structure.

8. The electronic device of claim 6, wherein the liquid cooling module further comprises a resilient member disposed between the replaceable fin structure and the cover.

9. The electronic device of claim 6, wherein the liquid cooling module further comprises a sealing ring disposed between the substrate and the cover.

10. The electronic device of claim 6, wherein the cover comprises a liquid inlet and a liquid outlet, and the fin accommodating region is located between the liquid inlet and the liquid outlet.
